(19) United States
(12) Patent Application Publication
(10) Pub. No.: US 2008/0157749 A1
(43) Pub. Date: Jul. 3, 2008

(54) METHOD AND RECEIVER FOR ESTIMATING DC OFFSET

(75) Inventor: KAR BOON OUNG, PENANG (MY)

Correspondence Address: MOTOROLA, INC., 1303 EAST ALGONQUIN ROAD, IL01/3RD, SCHAUMBURG, IL, 60196, US

(73) Assignee: MOTOROLA, INC., SCHAUMBURG, IL (US)

(21) Appl. No.: 11/618,956

(22) Filed: Jan. 2, 2007

(51) Int. Cl. G01R 29/00; G06F 3/033

(52) U.S. Cl. 324/76.12; 455/130

(57) ABSTRACT

A method for estimating a DC offset in a received signal, the method comprising: detecting a plurality of zero crossings of the signal (220); determining a variable time window (235) based upon a predetermined number of said detected zero crossings (230); estimating the DC offset (240) of the signal in the variable time window from at least one minimum amplitude and at least one maximum amplitude of the signal (215) in the variable time window.

### FIELD OF THE INVENTION

This invention relates in general, to communication systems, and more specifically to error correction occurring in a received signal of a communication system.

### BACKGROUND OF THE INVENTION

Communication systems utilizing radio frequency (RF) signals often convert the received signal into an in-phase (I) component and a quadrature (Q) component. A mismatch in the electrical components in these signal channels causes I/Q imbalances in the received signal. The I/Q imbalances, such as amplitude imbalance and phase imbalance, are frequency-dependent and highly unpredictable. For communication systems where the received signal is converted into its constituent baseband I/Q components (e.g., direct conversion receivers (DCR)), the I/Q mismatch and intrinsic local oscillator (LO) self-mixing will introduce a direct current (DC) offset error in base-band I/Q signals. These errors degrade the signal quality, hence detection and correction of these errors becomes necessary.

The DC offset is time-varying due to signal fading and other propagation or transmission and reception system factors. For example, frequency offset variation of the carrier signal and zero netting errors in a DCR can result in poor DC offset estimates, in turn resulting in signal processing errors. In one known digital private line (DPL) access system, phase transitions occur periodically in the carrier signal and can result in erroneous DC offset estimates.

Various methods are known in the art for estimating DC offset. In one method, an integration of the amplitude of the I or Q baseband signal is performed over a moving window or time period. However, this method suffers from excursions in the estimation when 180 degree phase transitions occur for DPL signaling. In another method, the received signal is divided into equal time periods, and the average signal amplitude for each time period is determined and used as the DC offset estimate for this time period. In real time processing, each DC offset estimate is then used to correct the signal in the subsequent period. However, this method can suffer from variations in the received carrier signal amplitude due to fast changing effects, such as fast-fading and DPL phase transitions. These effects can be mitigated to some extent by extending the duration of the time periods in order to even out these effects over a longer period, however, this increases the tracking and correction response time to changes in DC offset.

### BRIEF DESCRIPTION OF THE DRAWINGS

The present invention is illustrated by way of example and not limitation in the accompanying figures, in which like references indicate similar elements, and in which:

FIG. 1 is a graph of a DPL received signal together with its DC estimate according to a prior art fixed time window method;

FIG. 2 is a schematic of a signal processing block for implementing DC estimation according to an embodiment of the present invention;

FIG. 3 illustrates variable time windows of a signal according to an embodiment of the present invention that can be implement implemented on the a signal processing block of FIG. 2;

FIG. 4 is a graph of a received signal further illustrating determination of variable time windows according to an embodiment of the present invention;

FIG. 5 is a flow chart illustrating a method of DC estimation used by the a signal processing block FIG. 2;

FIG. 6 is a graph of a DPL received signal together with its DC estimate according to a variable time window method used by the a signal processing block FIG. 2; and

FIGS. 7a and 7b are respectively graphs of a received signal together with DC offsets estimated according to a prior art fixed time window method and the variable time window method.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE EMBODIMENTS

Briefly, in accordance with the present invention, there is disclosed herein a method for estimating and correcting DC offsets in a signal, for example an in-phase (I) or quadrature phase (Q) baseband signal in a direct conversion receiver. The method includes the steps of resolving or determining the signal into a number of variable time windows or periods which each include or are based upon a predetermined number of detected zero crossings. A zero crossing is a point at which the signal waveform amplitude or voltage is zero (or some other predetermined baseline level) or at which the polarity of the signal amplitude or voltage changes, for example from negative to positive. Where the signal is resolved into a plurality of discrete samples for digital signal processing, a zero crossing can be detected at a sample which has a different voltage or amplitude polarity to the preceding sample; or its value is zero. However, various methods of detecting zero crossings will be well known to those skilled in the art, and these can alternatively be employed in the embodiments. In an embodiment, detection of the zero crossings comprises ignoring some zero crossings which are spaced too closely together in order to avoid detecting zero crossings present due to noise rather than the wanted signal.

The DC offset for each variable time window or period is then estimated dependent on at least one maximum signal voltage or amplitude and at least one minimum signal voltage or amplitude within the variable time window of the signal. For example the maximum value sample and the minimum value sample within the variable time window may be averaged. Alternatively, all of the samples in the variable time window may be averaged. In a real-time system, the estimated DC offset from one variable time window may then be removed from the signal in the next variable time window. Alternatively, the DC offset may be removed from the signal in the variable time window from which it was estimated, for example when analyzing the signal in non-real time.

Before describing in detail the particular method and system for DC offset estimation and/or correction in accordance with the present invention, it should be observed that the present invention resides primarily in combinations of method steps and apparatus components related to method and system for DC offset estimation and/or correction. Accordingly, the apparatus components and method steps have been represented where appropriate by conventional symbols in the drawings, showing only those specific details that are pertinent to understanding the present invention so as not to obscure the disclosure with details that will be readily apparent to those of ordinary skill in the art having the benefit of the description herein.

A “set” as used in this document, means a non-empty set (i.e., comprising at least one member). The term “another”, as used herein, is defined as at least a second or more. The terms “including” and/or “having”, as used herein, are defined as comprising.

It is further understood that the use of relational terms, if any, such as first and second, top and bottom, and the like, are used solely to distinguish one entity or action from another, without necessarily requiring or implying any actual relationship or order between such entities or actions.

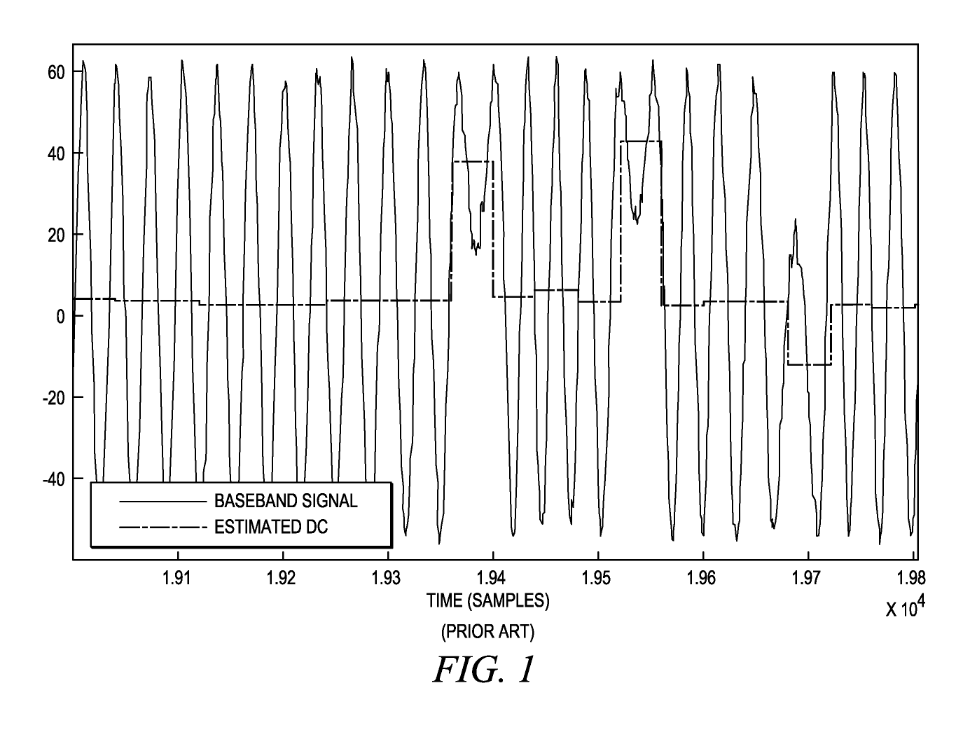

FIG. 1 is a graph illustrating the effect of DPL phase transitions on a received baseband signal in an in-phase (I) or quadrature phase (Q) signal path of a DCR. As can be seen, during these phase transitions the trough or minimum amplitude of the received signal's sinusoidal waveform is elevated above the usual zero crossing line at 0 V. This causes an increase in the average signal amplitude or voltage which is used in known methods to estimate the DC offset for a fixed period or time window.

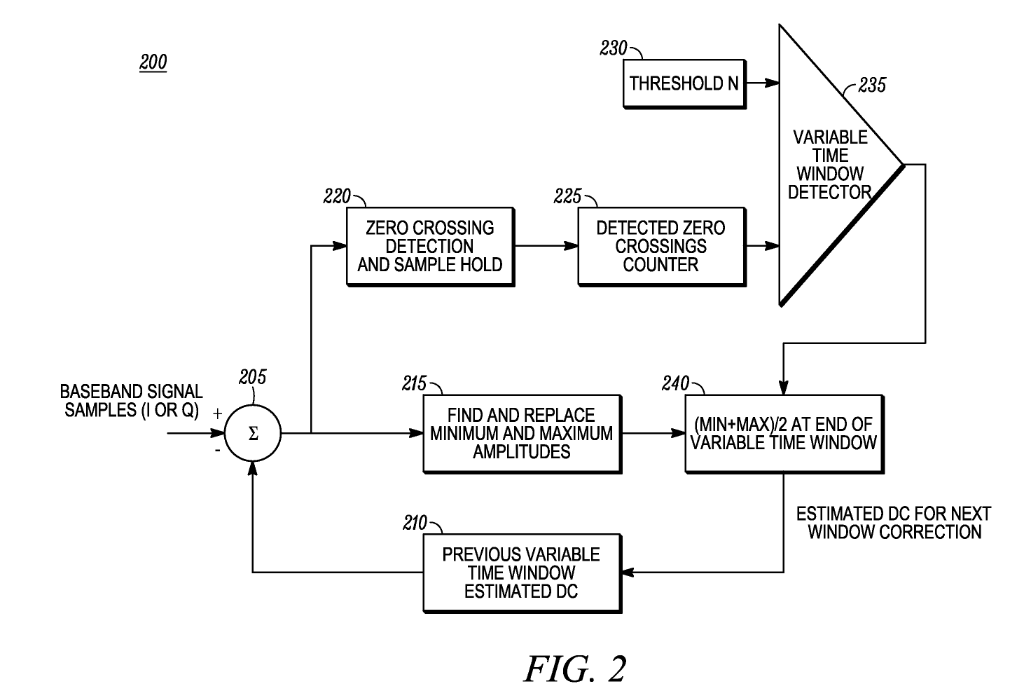

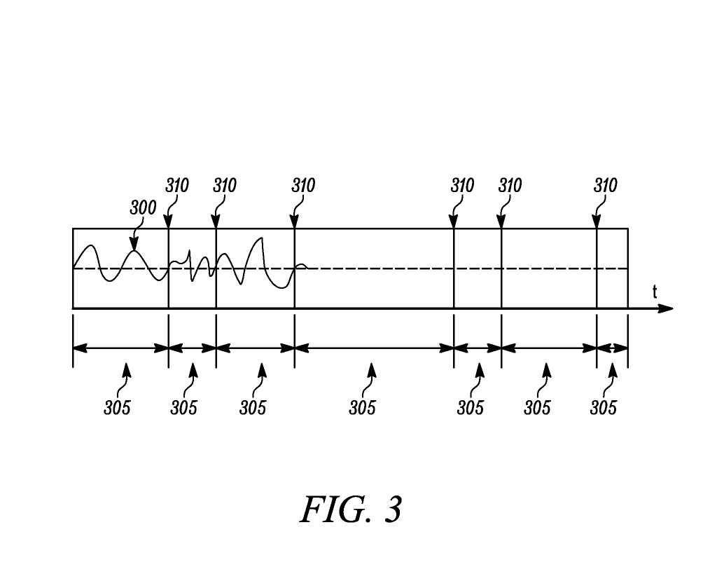

FIG. 2 illustrates a real-time digital signal processing block schematic according to an embodiment. The digital signal processing block 200 may be implemented in a digital signal processing core, a software-driven microprocessor, an ASIC, or any other suitable circuitry or software. The digital signal processing block 200 receives a digital signal in the form of a plurality of discrete samples corresponding to the amplitude or voltage of an I or Q baseband signal received and detected by a direct conversion receiver such as a DPL receiver. The received signal samples are input to a summer 205 which subtracts a DC offset 210 from each sample. The DC offset 210 has been estimated from a previous variable time window of the signal. Each variable time window of the signal is based on or defined by a predetermined number of detected zero crossings. In this embodiment, four detected zero crossings have been found to provide a good compromise between the increased accuracy of DC offset estimation over a longer time window, and the need for a fast response to changes in DC offset in the received signal and hence a shorter time window. However, each variable time window could be based on a lesser or greater number of detected zero crossings. Because the received signal will normally be varying, the time it takes to detect four zero crossings will also vary, and hence the windows into which the signal is resolved or determined will normally be of different durations or variable time lengths as illustrated in FIG. 3. Here, the signal is generally indicated as 300, and each variable time window 305 is based on a predetermined number N (e.g., 4) of detected zero crossings. After each Nth detected zero crossing 310, a new variable time window 305 is started. It can be seen from FIG. 3 that the time windows 305 will normally be of variable duration.

Returning to FIG. 2, a maximum and minimum received signal sample amplitude block 215 determines the maximum received signal sample value, for example, the voltage highest peak of the signal waveform, and the minimum received signal sample value, for example, the lowest or most negative voltage of the signal waveform, over the current variable time window 305. A zero crossing detector block 220 also examines each received signal sample to determine whether it has an amplitude of the opposite polarity (e.g., negative) to the amplitude of the preceding received signal sample (e.g., positive), or that the received signal sample amplitude is zero. In either of these cases, a zero crossing is detected. The embodiment is therefore able to detect a plurality of zero crossings in the received signal. However in this embodiment, a sample and hold mechanism is employed in the zero crossing detector 220. Once a zero crossing has been detected, then the zero crossing detector 220 does not attempt to detect a subsequent zero crossing for a predetermined or minimum hold duration, for example, a predetermined number of samples. This may mean that not all zero crossings in the received signal are detected in some embodiments. The benefit of this hold duration is to minimize detection of zero crossings due to noise rather than the received signal as described in more detail below.

A zero crossing counter 225 counts the number of detected zero crossings from the zero crossing detector 220. This count number is compared against a predetermined threshold or number of detected zero crossings (N) 230 by a comparator 235. As noted above, in an exemplary embodiment, the predetermined number of detected zero crossings N is four. When four zero crossings have been detected by the zero crossing detector 220 and counter 225, the comparator 235 indicates or detects the end 310 of one variable time window 305 and the start of the subsequent variable time window. The end of a variable time window indication from the comparator 235 triggers an averaging block 240 which averages the maximum and minimum received signal sample amplitudes in the just ended variable time window. This average received signal amplitude (e.g., (Vₘₐₓ+Vₘᵢₙ)/2) is then taken as the DC offset estimate for the just ended variable time window. This DC offset estimate is stored in the DC offset estimate block 210, and applied to the negative input of the summer 205 where it is typically subtracted from the incoming signal samples for the next variable time window of the signal. This estimated DC offset may also be removed from the incoming signal by subtracting the incoming signal from the estimated DC offset in order to obtain an inverted (DC offset corrected) signal for the new variable time window.

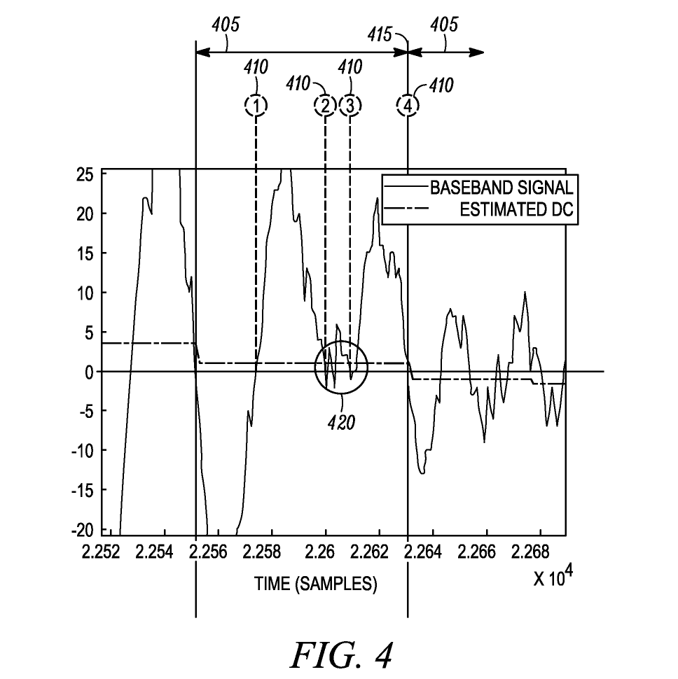

FIG. 4 is a graph showing a signal waveform with superimposed detected zero crossing and variable time window information according to an embodiment. One variable time window 405 of the signal (solid line) is indicated, and each of the detected zero crossings 415 are also indicated (1, 2, 3, and 4 in broken line). It can be seen that a zero crossing occurs in this embodiment when the received signal amplitude changes from a positive to a negative voltage, or vice versa. It is also contemplated however that a zero crossing may refer to a signal transgression of any base line amplitude, for example, if there was a DC bias of 5V and the signal varied about this base line, then the signal crossing this (5V) baseline voltage would be considered a zero crossing. After four zero crossings are detected 410, a new variable time window 405 is started. Thus, the duration of the variable time window is based upon the time it takes for a predetermined number (e.g., four) of zero crossings 415 to be detected. Although four detected zero crossings 415 have been detected, in fact further zero crossings have occurred which has not been detected. This is because of the hold duration implemented in the zero crossing detector 220 of FIG. 4. As shown in the circled detail 420, following detection of the second zero crossing 415, three further zero crossings occur before a third zero crossing 415 is detected. These intermediate zero crossings are within the hold duration following detection of the second zero crossing 415, and are therefore not detected in this embodiment. This avoids false zero crossings being detected due to noise variance near the zero crossing voltage during weak signal or bad fading conditions. In this embodiment, a hold duration of five signal samples is used, however different numbers of samples or a fixed time period may also be used for the minimum hold duration.

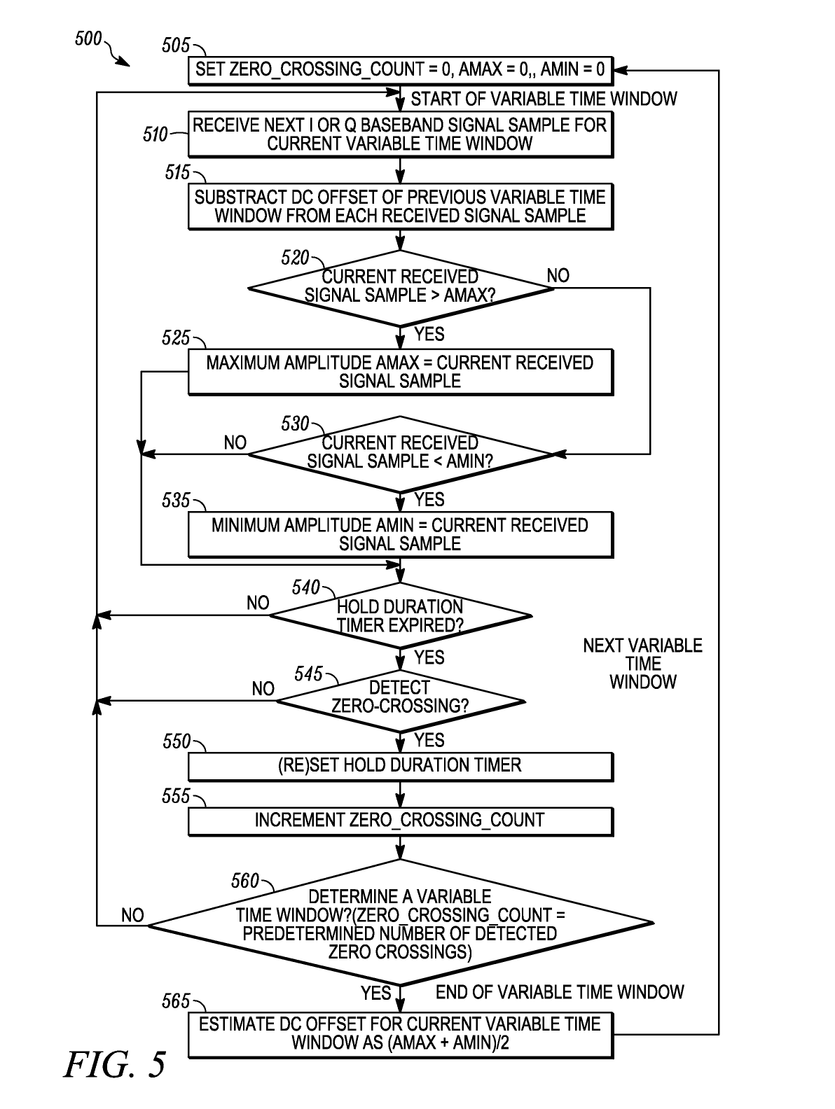

FIG. 5 illustrates a method of estimating the DC offset for a signal according to an embodiment. This method 500 may be implemented as a computer program executed on a processor, or hardwired into an ASIC or other digital circuit. The method 500 in a first step 505 initially sets variables zero_crossing_count, Amax, and Amin to zero. The method at step 510 then receives the first/next sample of an I or Q baseband received signal for a new/current variable time window. The DC offset estimate from the previous variable time window of the signal is then removed in step 515, for by example subtracting. The first variable time window of the signal will have no DC offset removed. Removing the DC offset estimate from the previous variable time window of the signal enables real-time processing of the signal. However, for non-real time processing, the actual DC offset estimate for the signal variable time window in question may be subtracted from the signal within the current variable time window prior to further processing.

The method at step 520 then determines whether the current signal sample has an amplitude greater than the Amax or maximum signal amplitude variable. If so (520Y), then the amplitude or current value of the current received signal sample is written to the Amax variable to replace its existing content at step 525. The method at step 540 then moves on to determine whether a hold duration timer has expired as described in more detail below. If, however, the voltage or amplitude of the current received signal sample is not greater than Amax (520N), the method at step 530 then determines whether the current signal sample has an amplitude less than the Amin or minimum signal amplitude variable. If so (530Y), then the amplitude or current value of the current signal sample is written to the Amin variable to replace its existing content at step 535. The method then moves on to determine whether the hold duration timer has expired at step 540. Similarly, if the voltage or amplitude value of the current sample is not greater than Amin (530N), the method at step 540 moves on to determine whether the hold duration timer has expired.

The hold duration timer is set each time a zero crossing is detected, and expires after a predetermined hold duration. In this digital implementation, the hold duration timer may have a predetermined hold duration of five sample periods, and is incremented with each iteration (sample) of the method 500. Thus, in this embodiment, the hold duration timer expires when it reaches (for example, is incremented to) the predetermined hold duration (e.g., five samples). Although not shown, this may be implemented in the method 500 with an extra step incrementing the timer following each receive sample step 510, for example. The hold duration timer in this implementation will have expired if it has a value over the predetermined hold duration, and will be reset by setting its timer value to zero. Those skilled in the art will appreciate that there are many alternative ways in which this hold duration may be implemented in alternative embodiments.

If the hold duration timer has not yet expired or otherwise has not been set (540N), then the method returns to receive the next signal sample at step 510. The method detects a plurality of zero crossings of the signal, assuming in this embodiment that this zero crossing detection waits for the hold duration before detecting a subsequent zero crossing. In this embodiment, if the hold duration has expired (for example, its value is five or greater samples), then the method detects whether a zero crossing has occurred at step 545. This is implemented by determining if the amplitude (e.g., voltage or current) of the previous received signal sample had the opposite polarity to the amplitude of the current received signal sample, or the current sample has an amplitude of zero. A plurality of zero crossings may be detected in subsequent samples of the received signal using this step (545Y) in subsequent iterations of the method 500. If no zero crossing is detected (545N), the method returns to receive the next signal sample at step 510. When a zero crossing is detected (545Y), the hold duration timer is reset (for example, to zero samples or a zero duration) at step 550. By resetting the hold duration timer at step 550 following each zero crossing detection (545), the method 500 then waits for the hold duration (e.g., five samples) before a subsequent zero crossing can be detected.

The zero_crossing_count variable is then incremented at step 555. The method determines a variable time window based upon a predetermined number of said detected zero crossings. In this embodiment, this is implemented by checking whether the zero_crossing_count variable has exceeded a predetermined number (e.g., N=4) of detected zero crossings at step 560. If a predetermined number of zero crossing have not been detected (560N), the method returns to receive the next signal sample at step 510. If, however, the predetermined number of zero crossings have been detected (560Y), the new DC offset is estimated as the average of the Amax and Amin variables at step 565: DC offset=(Amax+Amin)/2. In other words, a variable time window is determined based upon the predetermined number (e.g., four) of detected zero crossings. When the variable time window is determined in this way, the DC offset for the current variable length window is estimated from the maximum and minimum signal sample amplitudes in the current variable length window. The method then returns to the initializing variables step 505 and then receives signal samples for a new variable time window at step 510.

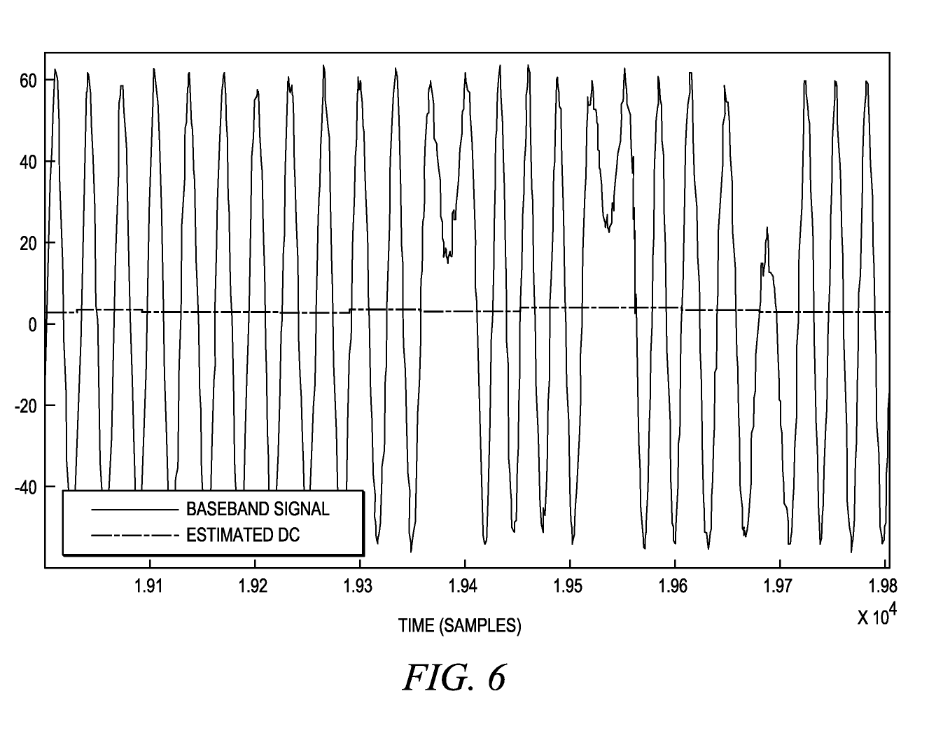

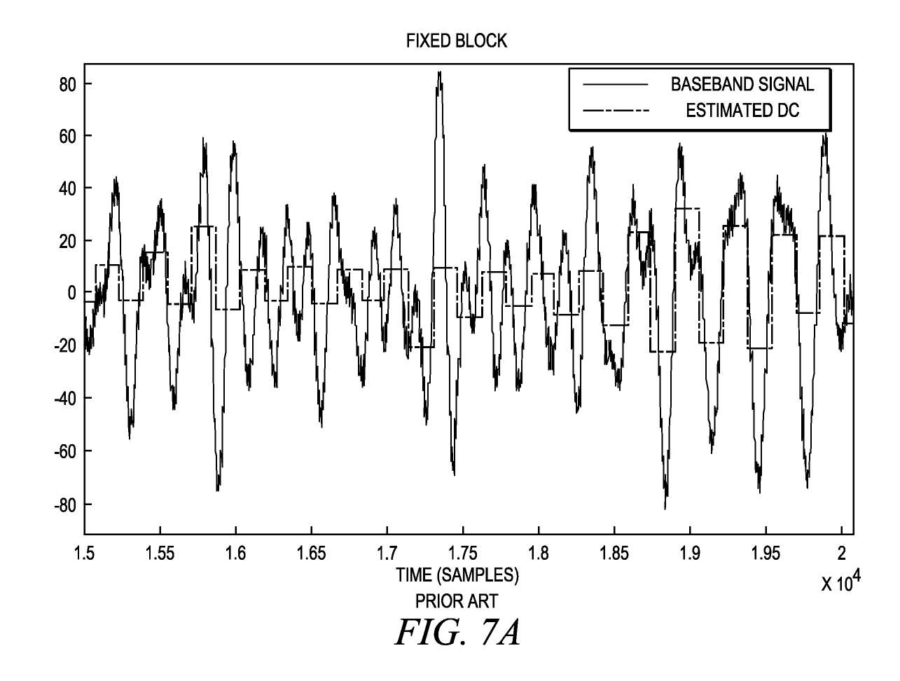

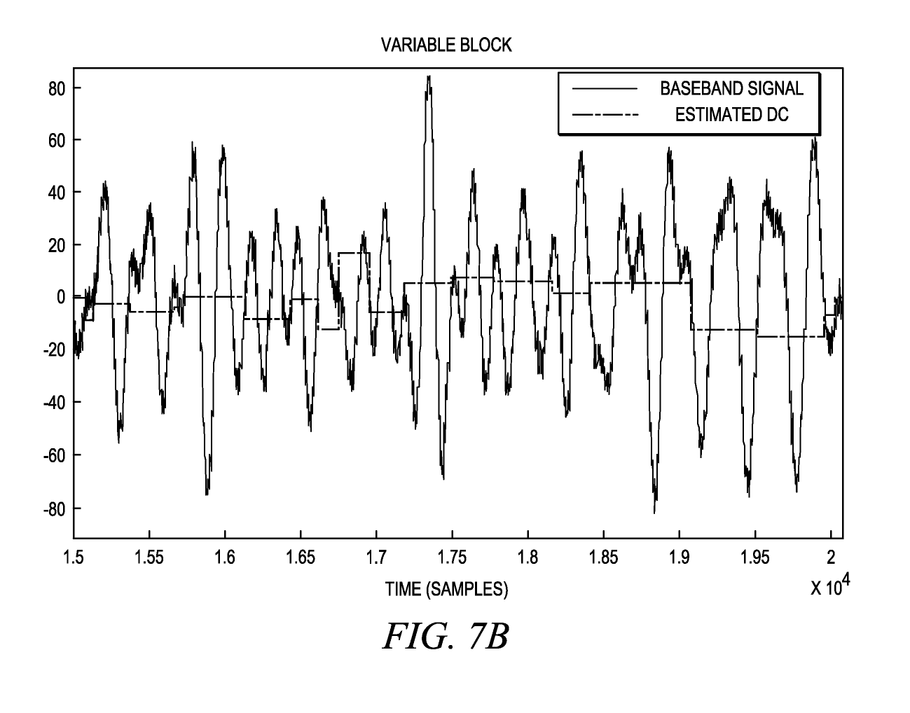

This method provides an improved DC offset estimate which in turn provides for improved DC offset correction of received signals, for example I and Q baseband DPL signals received in a direct conversion receiver. In particular, the effects of the DPL phase shift are largely mitigated, as can be seen, for example, in FIG. 6 where the DC offset estimate is much more linear and accurate compared with a DC offset estimated according to a known fixed duration window as illustrated in FIG. 1. A comparison between the known fixed time window DC offset estimation technique and that of an embodiment can also be seen in FIGS. 7A and 7B, respectively. Again, for the same received signal, the DC offset estimate is much improved when using the method of the embodiment (FIG. 7B) compared with the known fixed time window method (FIG. 7A). In addition, the hold duration following a zero crossing detection according to an embodiment mitigates the effects of noise variance on the DC offset estimation, especially near the zero crossing sample values.

In the foregoing specification, the invention and its benefits and advantages have been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method of estimating a direct current (DC) offset in a signal, the method comprising:
detecting a plurality of zero crossings of the signal;
determining a variable time window based upon a predetermined number of the detected zero crossings;
estimating the DC offset of the signal in the variable time window from at least one minimum amplitude and at least one maximum amplitude of the signal in the variable time window.

2. The method of estimating the DC offset in the signal as claimed in claim 1, wherein detecting the plurality of zero crossings of the signal comprises waiting a hold duration before detecting a subsequent zero crossing.

3. The method of estimating the DC offset in the signal as claimed in claim 2, wherein the signal comprises a plurality of discrete samples and the hold duration is a predetermined number of samples.

4. The method of estimating the DC offset in the signal as claimed in claim 3, wherein estimating the DC offset of the signal in the variable time window comprises averaging the amplitudes of the samples of the signal over the variable time window.

5. The method of estimating the DC offset in the signal as claimed in claim 1, wherein estimating the DC offset of the signal in the variable time window comprises averaging the maximum and minimum amplitudes in the variable time window.

6. The method of estimating the DC offset in the signal as claimed in claim 1, wherein the predetermined number of detected zero crossings is four.

7. A method of correcting for a direct current (DC) offset in a signal, the method comprising:
detecting a plurality of zero crossings of the signal;
determining a variable time window based upon a predetermined number of said detected zero crossings;
estimating the DC offset of the signal in the variable time window from at least one minimum amplitude and at least one maximum amplitude of the signal in the variable time window; and
removing the DC offset estimated for the variable time window of the received signal from the subsequent variable time window of the received signal.

8. A receiver comprising:
an input for receiving a signal;
a processor arranged to detect a plurality of zero crossings of the received signal;
the processor further arranged to determine a variable time window of the received signal based upon a predetermined number of detected zero crossings, and to estimate a direct current (DC) offset of the signal in the variable time window from at least one minimum amplitude and at least one maximum amplitude of the signal in the variable time window.

9. The receiver as claimed in claim 8, wherein the processor is further arranged to wait a hold duration before detecting a subsequent zero crossing.

10. The receiver as claimed in claim 8, wherein the processor is further arranged to average the maximum and minimum amplitudes in the variable time window in order to estimate the DC offset of the signal in the variable time window.

11. The receiver as claimed in claim 8, wherein the receiver is a direct conversion receiver.

12. The receiver as claimed in claim 8, wherein the receiver is part of a digital subscriber line receiver.
